(19) United States
(12) Patent Application Publication
(10) Pub. No.: US 2006/0223309 A1
(43) Pub. Date: Oct. 5, 2006

(54) Dual-damascene process for manufacturing semiconductor devices

(75) Inventors: Bang-Ching Ho, Hsin-Chu (TW); Jen-Chieh Shih, Yongkang City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/095,278

(22) Filed: Mar. 31, 2005

(51) Int. Cl. H01L 21/44

(52) U.S. Cl. 438/652

(57) ABSTRACT

The present disclosure relates generally to the manufacturing of semiconductor devices, and more particularly to a dual-damascene process for the manufacturing of semiconductor devices. A method of forming a dual-damascene structure includes forming a via hole and filling the via hole at least partially with a first plug material. A portion of the first plug material is removed and the remaining via hole is filled with a second plug material. A portion of the second plug material can also be removed.

### CROSS-REFERENCE

The present application is related to U.S. Pat. No. 6,488,509, U.S. patent application Ser. No. 10/789,083, and U.S. patent application (Attorney Docket No. N1085-00255/TSMC 2003-0509 filed on Jan. 31, 2004 and entitled “Method for Forming Dual Damascene Interconnect Structure”), each of which is hereby incorporated by reference in its entirety.

### BACKGROUND

The present disclosure relates generally to the manufacturing of semiconductor devices, and more particularly to a damascene process utilized in semiconductor manufacturing.

With increased device density, the available area for circuit wiring becomes a potential limiting factor in device performance. Such a limitation has led to the development of multi-layer wiring and the adoption of damascene and dual-damascene structures. During a damascene process, interconnect metal lines are delineated in dielectric and isolated from each other by planarization. First, an interconnect pattern is lithographically defined in the layer of dielectric. Then, metal is deposited to fill resulting trenches, and excessive metal is removed by chemical mechanical polishing planarization.

A dual-damascene process is a modified version of the damascene process. It is used to form metal interconnect geometry using planarization such as chemical mechanical polishing. During the process, two interlayer dielectric patterning steps and one chemical mechanical polishing step are generally employed to create a required pattern. During a dual-damascene process, a metal via plug is first formed in a surface, which may be the surface of a semiconductor substrate. A layer of dielectric is deposited over the surface, and trenches (for metal lines) are formed in the dielectric. Metal is then deposited to fill the trenches, and excessive metal over the surface is removed. As a result, a planar structure of interconnect lines with metal inlays in the dielectric is achieved.

It is desired to provide a damascene or dual-damascene process with reduced defects. Typical defects include fencing, damaged etch-stop layers, residue, and so forth.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1, 9, and 11 are flow charts of various methods for forming a semiconductor device utilizing a dual-damascene process according to embodiments of the present invention.

FIGS. 2-8 and 10 are cross-sectional views of semiconductor devices formed pursuant to the methods of FIGS. 1, 9 and 11 according to one or more embodiments of the present invention.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

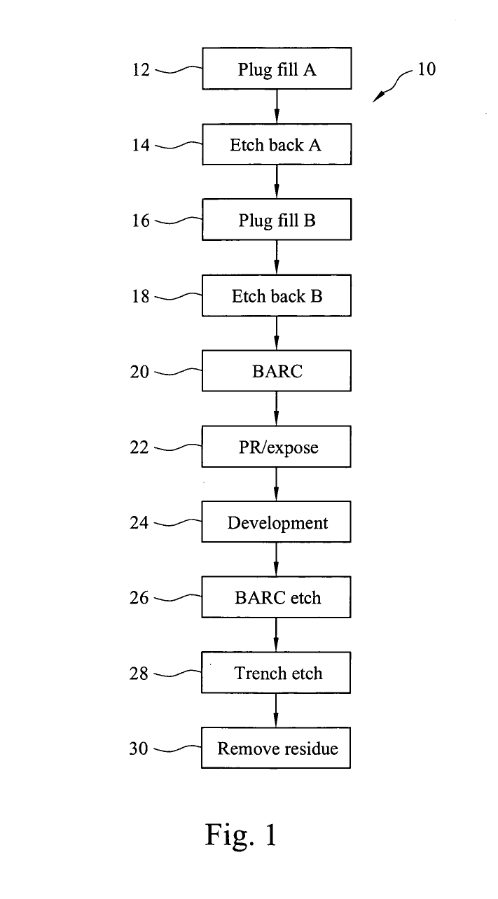

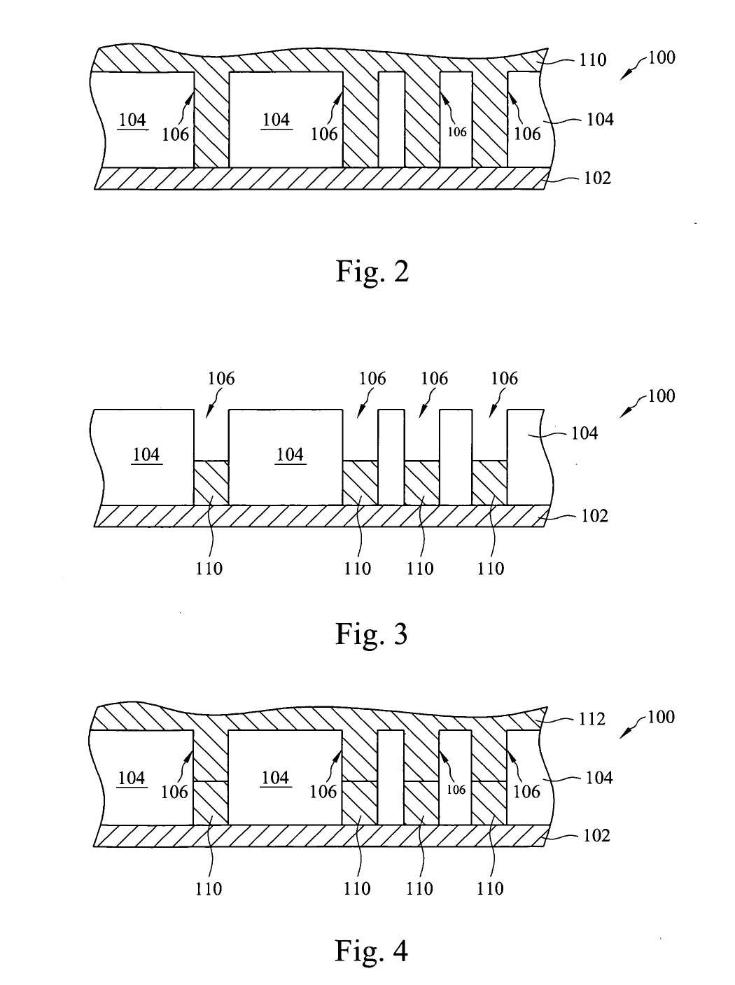

Referring now to FIG. 1, according to one embodiment of the present invention, a method 10 can be used for a dual-damascene process for manufacturing semiconductor devices. For the sake of example, a semiconductor device will be discussed with reference to FIGS. 2-8 along with the discussion of the steps of method 10.

The method 10 begins at step 12 in which a patterned insulative layer is filled with a first plug fill material. Referring also to FIG. 2, a semiconductor device 100 includes a substrate 102 which may be conductive or semiconductive. Examples of a substrate 102 include aluminum, aluminum alloy, copper, copper alloy, tungsten, and/or other conductive materials. Examples of a semisubstrate 102 include an elementary semiconductor, such as crystal silicon, polycrystalline silicon, amorphous silicon, and/or germanium; a compound semiconductor, such as silicon carbide and/or gallium arsenic; and an alloy semiconductor, such as SiGe, GaAsP, AlInAs, AlGaAs, and/or GaInP. Further, the substrate 102 may include a bulk semiconductor, such as bulk silicon, and such a bulk semiconductor may include an epi silicon layer. It may also or alternatively include a semiconductor-on-insulator substrate, such as a silicon-on-insulator (SOI) substrate, or a thin-film transistor (TFT) substrate. The substrate 102 may also or alternatively include a multiple silicon structure or a multilayer compound semiconductor structure. The substrate 102 may include transistors, diodes, resistors, capacitors or other circuit elements.

The semiconductor device 100 also includes an insulative layer 104. The insulative layer 104 (also referred to as a dielectric layer) may be formed by CVD, PECVD, ALD, PVD, spin-on coating and/or other processes. The insulative layer 104 may be an inter-metal dielectric (IMD), and may include low-k materials, silicon dioxide, polyimide, spin-on-glass (SOG), fluoride-doped silicate glass (FSG), Black Diamond® (a product of Applied Materials of Santa Clara, Calif.), Xerogel, Aerogel, amorphous fluorinated carbon, and/or other materials.

The insulative layer 104 is patterned, such as by photolithography, etching, and/or other means, to form one or more openings 106, thereby exposing a portion of the underlying substrate 102. For the sake of example, the openings 106 will be hereinafter referred to as via holes (also called contact holes).

In some embodiments, one or more barrier layers and/or etch-stop layers may be provided above the substrate 102 and/or in the openings 106, such as by self-ionized plasma (SIP) PVD and/or ionized metal plasma (IMP) PVD. The barrier layer may include Ta, TaN, Ti, TiN, and/or other barrier materials. In furtherance of the example, the bottom portion of a barrier layer proximate the substrate 102, whether formed prior to or after removing a portion of the insulative layer 104, may be removed by in-situ sputtering utilizing SIP or IMP. Consequently, at least a portion of the substrate 102 may be exposed.

The openings 106 may be at least partially filled with a first plug filler material 110 by a damascene process or other methods. In one embodiment, one or more seed layers comprising copper, copper alloys, and/or other seed materials may be deposited initially, thereby lining the opening 106 by PVD, IMP, SIP, and/or other processes. The openings 106 may then be filled with the first plug filler material 110 that may include materials substantially similar to that of the substrate 102. In one example, the first plug filler material 110 may include one ore more low etching rate materials (relative to a second conductive plug described below), such as para-hydroxy styrene (PHS), Novolake, and/or other suitable materials. The conductive material employed to form the first plug filler material 110 may be formed in the opening 106 by spin coating and/or other deposition processes.

At step 14 of method 10 (FIG. 1), a first etch-back process is performed on the first plug-filler material. Referring also to FIG. 3, in continuance of the present example, the first etch-back process 12 may utilize dry etching, wet etching, chemical etching, or other etching processes. The first etch-back process 12 removes at least a portion of the first plug filler material 110 as shown in FIG. 3.

At step 16 of method 10, a second plug fill material is deposited into the previously formed openings. Referring also to FIG. 4, in continuance of the present example, a second plug filler material 112 is provided in the openings 106. The second plug filler material 112 may be deposited by a damascene process or other methods. The second plug filler material 112 may include materials substantially similar to that of the substrate 102. In one example, the second plug filler material 112 may include one ore more high etching rate materials (relative to the first plug 106), such as Acrylate, Methacrylate, and/or other suitable materials. Polymer material employed to form the second plug filler material 112 may also be formed in the opening 106 by spin coating and/or other deposition processes.

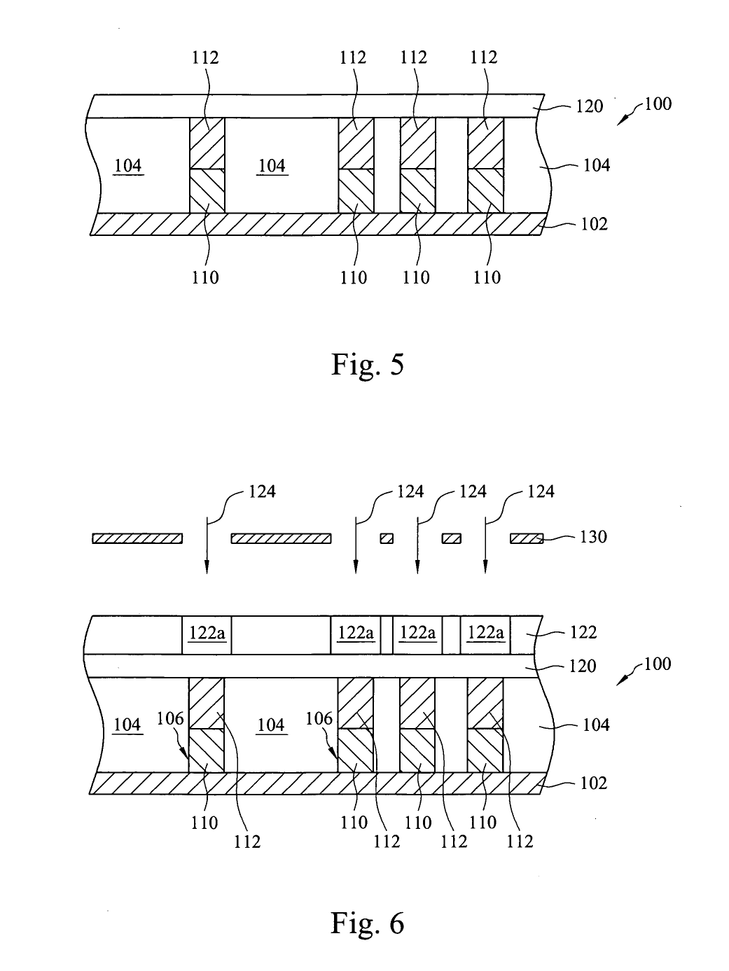

At step 18 of method 10 (FIG. 1), a second etch-back process is performed on the second plug-filler material. Referring also to FIG. 5, in continuance of the present example, the second etch-back process 18 may utilize dry etching, wet etching, chemical etching, or other etching processes. The second etch-back process may also use chemical mechanical polishing (CMP) or other suitable processes. The second etch-back process 12 removes at least a portion of the second plug filler material 112 to a point near a top surface of the insulative layer 104.

At step 20 of method 10, a liner layer may be formed over the insulative layer. With continued reference to FIG. 5, a bottom anti-reflective coating (BARC) layer 120 is formed over insulative layer 104. The BARC layer 120 may include SiON, SiOC, SiN, TaN, or any other suitable materials.

At steps 22 and 24 of method 10 (FIG. 1), a patterning process is performed. Referring also to FIG. 6, in continuance of the present example, a trench masking layer 122 is formed over the BARC layer 120. In the present embodiment, step 22 refers to a photolithography process where the trench masking layer 122 is a layer of photoresist that is responsive to a radiation source 124 provided through a mask (or reticle) 130. The radiation source 124 may be a suitable light source such as an ultra-violet (UV), deep ultra-violet (DUV), or extreme ultra-violet (EUV) source. For example, the radiation source 124 may be, but not limited to, a mercury lamp having a wavelength of 436 nm (G-line) or 365 nm (I-line); a Krypton Fluoride (KrF) excimer laser with wavelength of 248 nm; an Argon Fluoride (ArF) excimer laser with a wavelength of 193 nm; a Fluoride (F₂) excimer laser with a wavelength of 157 nm; or other light sources having a wavelength below approximately 100 nm. The photoresist layer 122 is of a type that is responsive to the radiation source 124, and may be either a positive or negative resist. At step 24 of the present embodiment, the photoresist layer 122 is developed by an alkaline developer, or by any other suitable methods, so that exposed portions of the layer, designated with the reference numeral 122a, can be removed. It is understood that various techniques are available for patterning, and that photolithography is only one example.

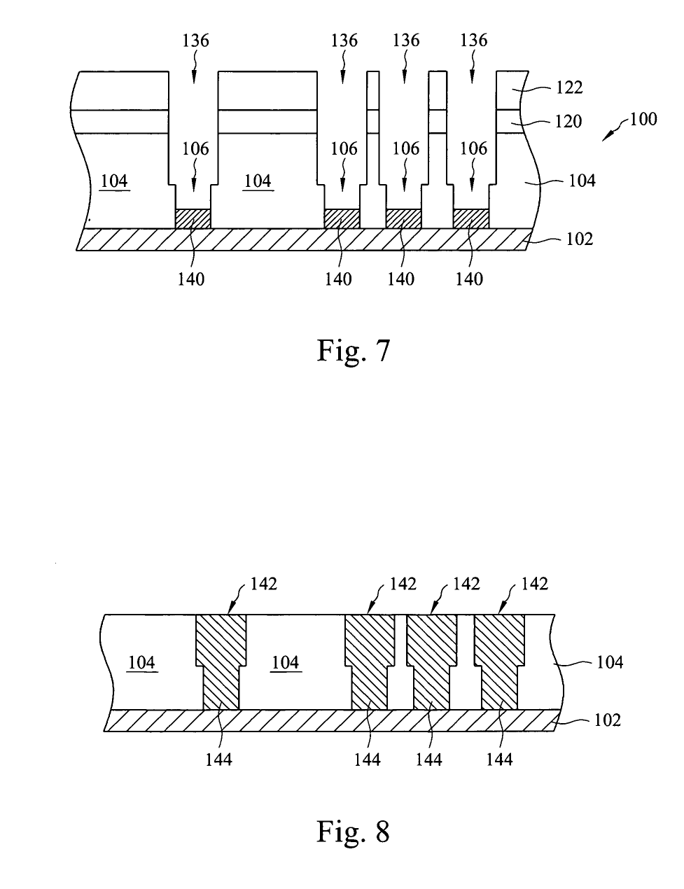

At step 26 of method 10 (FIG. 1), the liner layer is removed and at step 28, a trench is formed in the insulative layer. Referring also to FIG. 7, in continuance with the present example, the exposed portions 122a are substantially centered over the openings 106 (although other orientations are also contemplated), and exposing a portion of the BARC layer 120. Etching, which may comprise dry etching, wet etching, chemical etching, or other processes, may be applied to remove the exposed portion of the BARC layer 120 to form an etched BARC layer.

At step 28 of the method 10, trench etching is performed. Trench etching may be a continuation of the process used to etch the BARC layer 120, or may be some other type of removal process, such as dry etching, wet etching, or chemical etching. The trench etching removes the second plug material filler 112 to form trench openings 136. After completion of the trench etching, or in continuation thereof, the first plug filler material 110 (and any portions of the second plug material filler 112) in the via holes 106 is etched away, leaving a portion of residue 140 (e.g., a resist residue and/or a portion of the first plug filler material 110). It is contemplated that the trench openings 136 may be formed prior to or following the formation of the etched via holes. The patterned trench mask layer 122 is used as a mask for removing a portion of the exposed insulator layer 104.

Since the residue 140 remains, the substrate 102 is protected from damage that may occur during the etch process. This avoids, for example, via hole punch-through into the substrate 102. The trench opening 136 and the etched via opening together form a dual-damascene opening.

At step 30 of method 10 (FIG. 1), any residue from the trench and via openings is removed and any remaining overlying layers are removed. Referring to FIG. 8, in continuance of the present example, the residue 140 is removed from the dual-damascene opening by a suitable method known in the art, and a dual-damascene opening 142 (includes the via opening 106 and the trench opening 136) is cleaned, if necessary. In addition, the BARC layer 120 and the photoresist layer 122 are removed. A metal filler material 144, such as copper, aluminum, gold, or any other suitable material, is utilized to fill the dual-damascene opening 142. Thereafter, the layer of metal filler material 144 is planarized, such as by chemical mechanical polishing (CMP), to form a planarized dual-damascene structure.

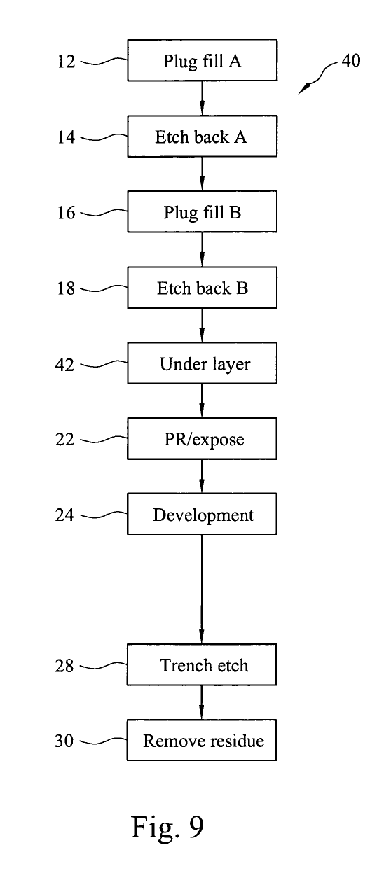

Referring now to FIG. 9, according to another embodiment of the present invention, a method 40 can be used for a dual-damascene process for manufacturing semiconductor devices. The method 40 uses many similar steps as discussed above with reference to method 10 of FIG. 1, and any necessary modifications to these steps not described below will be well understood by those of ordinary skill in the art.

The method 40 begins at step 12 in which a patterned insulative layer is filled with a first plug fill material. Execution then proceeds through steps 14-18 which are similar to the like-numbered steps of method 10 and the examples of FIGS. 3-5.

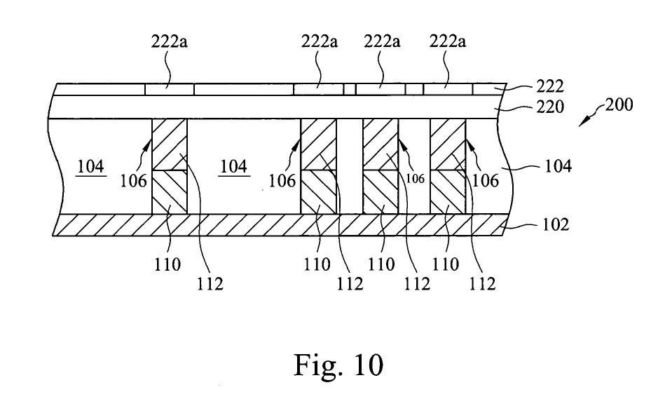

At step 42 of method 40, an under-layer is provided. Referring to FIG. 10, for the sake of example, a semiconductor device 200 has been processed according to steps 12-18 discussed above. An under-layer 220 is provided over the insulative layer 104. The under-layer 220 may be formed for a bi-layer process. The under layer may include a derivative of Acrylyate, Methacrylate, para-hydroxy styrene (PHS), a crosslink polymer, and/or other materials.

Execution then proceeds to steps 22 and 24 of method 40 (FIG. 9), where a patterning process is performed. Referring again to FIG. 10, in continuance of the present example, a thin masking layer 222 is formed over the under-layer 220. The masking layer 222 may serve as the image layer, which may include materials such as Si, Ti, a polymer with metal, and/or other materials. The patterning and developing process may be performed in a manner similar to that discussed above with reference to the like-numbered steps discussed above.

Execution then proceeds to steps 28 and 30 where trench etching and residue removal are performed. Trench etching and residue removal may be similar to the method discussed above with reference to method 10 of FIG. 1.

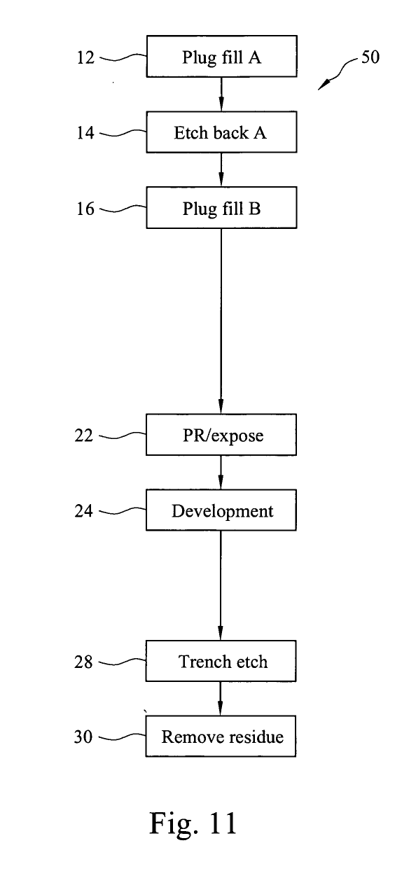

Referring now to FIG. 11, according to another embodiment of the present invention, a method 50 can be used for a dual-damascene process for manufacturing semiconductor devices. The method 50 uses many similar steps as discussed above with reference to method 10 of FIG. 1 and method 40 of FIG. 9, and any necessary modifications to these steps not described below will be well understood by those of ordinary skill in the art.

The method 50 begins at step 12 in which a patterned insulative layer is filled with a first plug fill material. Execution then proceeds through steps 14 and 16 which are similar to the like-numbered steps of method 10 and the examples of FIGS. 3-5.

Instead of providing a separate under-layer as discussed above with respect to step 42 of method 40, the second plug filler material 112 serves as the under-layer, which may include materials such as Si, Ti, a polymer with metal, and/or other materials.

Execution then proceeds to steps 22 and 24 of method 50 (FIG. 10), where a patterning and developing process is performed. The patterning and developing process may be performed in a manner similar to that discussed above with reference to the like-numbered steps discussed above.

Execution then proceeds to steps 28 and 30 where trench etching and residue removal may be performed. Trench etching and residue removal may be similar to the method discussed above with reference to the like-numbered steps discussed above.

Although only a few exemplary embodiments of this disclosure have been described in details above, those skilled in the art will readily appreciate that many modifications are possible in the exemplary embodiments without materially departing from the novel teachings and advantages of this disclosure. Also, features illustrated and discussed above with respect to some embodiments can be combined with features illustrated and discussed above with respect to other embodiments. Accordingly, all such modifications are intended to be included within the scope of this disclosure.

What is claimed is:

1. A method of forming a dual-damascene structure, comprising:
forming a via hole;
filling the via hole at least partially with a first plug material;
removing a portion of the first plug material;
filling the remaining via hole with a second plug material; and
removing a portion of the second plug material.

2. The method of claim 1 wherein the first plug material comprises a low etching rate material, as compared to the second plug material.

3. The method of claim 2 wherein the low etching rate material comprises para-hydroxy styrene (PHS).

4. The method of claim 2 wherein the low etching rate material comprises Novolake.

5. The method of claim 1 wherein the second plug material comprises a high etching rate material.

6. The method of claim 5 wherein the high etching rate material comprises Acrylate.

7. The method of claim 5 wherein the high etching rate material comprises Methacrylate.

8. The method of claim 1 further comprising:
etching a portion of a insulative layer to form a trench opening that is substantially centered over the via hole for forming a dual-damascene opening.

9. The method of claim 8 wherein the insulative layer is over a substrate.

10. The method of claim 1 further comprising forming an anti-reflective coating (ARC) layer over the via hole.

11. A partial semiconductor device, comprising a structure for forming a dual-damascene process, wherein the structure comprises:
a via hole;
a low etching rate plug material filling the bottom portion of the via hole; and
a high etching rate plug material filling the upper portion of the via hole.

12. The partial semiconductor device of claim 11 wherein the low etching rate material comprises para-hydroxy styrene (PHS).

13. The semiconductor device of claim 11 wherein the low etching rate material comprises Novolake.

14. The semiconductor device of claim 11 wherein the high etching rate material comprises Acrylate.

15. The semiconductor device of claim 11 wherein the high etching rate material comprises Methacrylate.

16. A method for forming a dual-damascene structure, comprising:
forming a substrate;
forming a dielectric layer over the substrate;
etching a portion of the dielectric layer to form a via hole;
filling the via hole at least partially with a low etching rate plug material;
etching a portion of the low etching rate plug material;
filling the remaining via hole with a high etching rate plug material;
etching the high etching rate plug material, if the high etching rate plug material is not used as an anti-reflective coating layer or an under layer for a bi-layer process; and
forming a dual-damascene opening.

17. The method of claim 17 wherein the trench opening of the dual-damascene opening is formed prior to forming the via opening of the dual-damascene opening.

18. The method of claim 17 wherein the via opening of the dual-damascene opening is formed prior to forming the trench opening of the dual-damascene opening.

19. The method of claim 17 wherein the high etching rate plug material is used as an anti-reflective coating layer.

20. The method of claim 17 wherein the high etching rate plug material is used as an under layer for a bi-layer process.
